(19) United States
(12) Patent Application Publication
(10) Pub. No.: US 2007/0267713 A1
(43) Pub. Date: Nov. 22, 2007

(54) COMMUNICATION DEVICE FOR TWO-DIMENSIONAL DIFFUSIVE SIGNAL TRANSMISSION

(75) Inventor: Tadashi MINAKUCHI, Saitama (JP)

Correspondence Address: GREENBLUM & BERNSTEIN, P.L.C., 1950 ROLAND CLARKE PLACE, RESTON, VA, 20191, US

(73) Assignee: PENTAX CORPORATION, Tokyo (JP)

(21) Appl. No.: 11/748,005

(22) Filed: May 14, 2007

(30) Foreign Application Priority Data
May 17, 2006 (JP) 2006-137666

(51) Int. Cl. H01L 29/00; H04J 3/08

(52) U.S. Cl. 257/499; 370/315

(57) ABSTRACT

A communication device capable of transmitting a signal by two-dimensional diffusive signal transmission technology includes: a signal layer in which the signal is transmitted; a plurality of communication chips which are connected to the signal layer to transmit the signal by the two-dimensional diffusive signal transmission technology; a power supply layer which supplies electric power to each of the communication chips; a ground layer which is electrically connected to each of the communication chips as ground for the electric power; and an attenuation layer which is placed between the signal layer and the power supply layer, attenuates electric current that can flow between the signal layer and the power supply layer, and pulls up electric potential of the signal layer toward that of the power supply layer.

### BACKGROUND OF THE INVENTION

The present invention relates to a communication device capable of transmitting signals by two-dimensional diffusive signal transmission technology.

A technology for transmitting a signal as packets to a destination by use of a plurality of elements (hereinafter referred to as “DST (Diffusive Signal Transmission) chips”) for relaying (successively receiving and transmitting) the signal has been proposed in recent years (hereinafter referred to as a “two-dimensional diffusive signal transmission technology” or “2D-DST technology”). In the two-dimensional diffusive signal transmission technology, signals are transmitted in a layer (extending along a two-dimensional plane) according to prescribed algorithm. Therefore, the 2D-DST technology does not require individual lines (patterns formed on a circuit board, jumper cables, etc.) for the signal transmission. Communication devices employing the two-dimensional diffusive signal transmission technology have been disclosed in Japanese Patent Provisional Publication No. 2003-188882A (hereinafter referred to as a “document #1”) and Japanese Patent Provisional Publication No. 2004-328409A (hereinafter referred to as a “document #2”), for example.

Each of the communication devices described in the documents #1 and #2 includes a signal layer for transmitting a signal between DST chips, a power supply layer for supplying electric power to each of the DST chips; a ground layer which is grounded to the ground potential, and insulating layers which are placed between the above layers. In a substrate of such a communication device, a power supply layer, a first insulating layer, a signal layer, a second insulating layer and a ground layer are stacked in this order, for example. The signal layer is insulated from the power supply layer and the ground layer by the first and second insulating layer, respectively.

As above, in each of the communication devices described in the documents #1 and #2, the signal layer and the power supply layer are placed to sandwich an insulating layer (first insulating layer). The signal layer and the ground layer are also placed to sandwich an insulating layer (second insulating layer). Each of the layers is thinly formed to extend along a two-dimensional plane. In this configuration, the power supply layer, the (first) insulating layer and the signal layer are in a state that is equivalent to two planar conductors placed closely in parallel with each other to sandwich a space having a certain dielectric constant. The signal layer, the (second) insulating layer and the ground layer are also in a similar state. Therefore, relatively large parasitic capacitance occurs between the power supply layer and the signal layer, and between the signal layer and the ground layer.

Therefore, the signal layer receives ill effects of the parasitic capacitance, from both the power supply layer's side and the ground layer's side. When the signal layer is affected by the parasitic capacitance as above, delays are caused to the signal transmission and the throughput of the communication device drops, for example. There is also a possibility that the gain of the transmitted signal fluctuates. With such gain fluctuation of the transmitted signal, a DST chip on the signal reception side might detect the changes in the voltage of the signal layer erroneously or incorrectly. In such cases where the voltage changes of the signal layer are erroneously detected by a DST chip, the signal (which should be transmitted correctly via the DST chip) can not be transmitted correctly. From this viewpoint, it is desirable that the ill effects of the parasitic capacitance on the signal layer be reduced as much as possible.

Here, it is possible to increase the thickness of each insulating layer to reduce the parasitic capacitance. However, this is not a desirable solution since the total thickness of the communication device is necessitated to grow considerably. It is also possible to form each insulating layer with material having a small dielectric constant. However, various factors of the material (flexibility, stretchability, weight, thickness, etc.) can impair the degree of freedom of the application of the 2D-DST technology. From this viewpoint, a solution independent of the material of the insulating layers is being desired.

Further, the communication devices described in the documents #1 and #2 involve problems other than the above parasitic capacitance problem. The problems are caused by the two insulating layers sandwiching the signal layer.

When the signal layer is sandwiched between insulating layers as above, the signal layer stays in a state disconnected (isolated) from the circuit of the communication device (i.e. the circuit is open) while the power of the communication device is OFF, by which the electric potential of the signal layer becomes unstable and that can lead to malfunction, etc. of the communication device. While the problem can be resolved by driving the signal layer from the circuit's side to keep the electric potential of the signal layer at that of the power supply layer or the ground layer, the method considerably increases the overall power consumption of the communication device.

### SUMMARY OF THE INVENTION

The present invention is advantageous in that a communication device for transmitting signals by the two-dimensional diffusive signal transmission technology, capable of reducing the ill effects of the parasitic capacitance on the signal layer while also stabilizing the electric potential of the signal layer by an effective and desirable method, can be provided.

In accordance with an aspect of the present invention, there is provided a communication device capable of transmitting a signal by two-dimensional diffusive signal transmission technology, comprising: a signal layer in which the signal is transmitted; a plurality of communication chips which are connected to the signal layer to transmit the signal by the two-dimensional diffusive signal transmission technology; a power supply layer which supplies electric power to each of the communication chips; a ground layer which is electrically connected to each of the communication chips as ground for the electric power; and an attenuation layer which is placed between the signal layer and the power supply layer, attenuates electric current that can flow between the signal layer and the power supply layer, and pulls up electric potential of the signal layer toward that of the power supply layer.

In at least one aspect, in the above communication device, resistivity of the attenuation layer is set at 10 to 1000 times that of the signal layer.

In a preferred embodiment, the layered structure of the communication device includes a first ground layer, a first signal layer, a first attenuation layer, a power supply layer, a second attenuation layer, a second signal layer and a second ground layer in this order. The communication chips may include: first communication chips which are connected to the first signal layer, the power supply layer and the first and second ground layers to transmit a first signal by the two-dimensional diffusive signal transmission technology; and second communication chips which are connected to the second signal layer, the power supply layer and the first and second ground layers to transmit a second signal by the two-dimensional diffusive signal transmission technology. The first attenuation layer is placed between the first signal layer and the power supply layer, attenuates electric current that can flow between the first signal layer and the power supply layer, and pulls up electric potential of the first signal layer toward that of the power supply layer. The second attenuation layer is placed between the second signal layer and the power supply layer, attenuates electric current that can flow between the second signal layer and the power supply layer, and pulls up electric potential of the second signal layer toward that of the power supply layer.

In accordance with another aspect of the present invention, there is provided a communication device capable of transmitting a signal by two-dimensional diffusive signal transmission technology, comprising: a signal layer in which the signal is transmitted; a ground layer which is grounded; a plurality of communication chips which are connected to the signal layer and the ground layer to transmit the signal by the two-dimensional diffusive signal transmission technology; a power supply layer which supplies electric power to each of the communication chips; and an attenuation layer which is placed between the signal layer and the ground layer, attenuates electric current that can flow between the signal layer and the ground layer, and pulls down electric potential of the signal layer toward that of the ground layer.

In at least one aspect, in the above communication device, resistivity of the attenuation layer is set at 10 to 1000 times that of the signal layer.

In a preferred embodiment, the layered structure of the communication device includes a first power supply layer, a first signal layer, a first attenuation layer, a ground layer, a second attenuation layer, a second signal layer and a second power supply layer in this order. The communication chips include: first communication chips which are connected to the first signal layer, the first and second power supply layers and the ground layer to transmit a first signal by the two-dimensional diffusive signal transmission technology; and second communication chips which are connected to the second signal layer, the first and second power supply layers and the ground layer to transmit a second signal by the two-dimensional diffusive signal transmission technology. The first attenuation layer is placed between the first signal layer and the ground layer, attenuates electric current that can flow between the first signal layer and the ground layer, and pulls down electric potential of the first signal layer toward that of the ground layer. The second attenuation layer is placed between the second signal layer and the ground layer, attenuates electric current that can flow between the second signal layer and the ground layer, and pulls down electric potential of the second signal layer toward that of the ground layer.

In accordance with another aspect of the present invention, there is provided a communication device capable of transmitting a signal by two-dimensional diffusive signal transmission technology, comprising: a signal layer in which the signal is transmitted; a plurality of communication chips which are connected to the signal layer to transmit the signal by the two-dimensional diffusive signal transmission technology; a power supply layer which supplies electric power to each of the communication chips; a ground layer which is electrically connected to each of the communication chips as ground for the electric power; a first attenuation layer which is placed between the signal layer and the power supply layer and at least attenuates electric current that can flow between the signal layer and the power supply layer; and a second attenuation layer which is placed between the signal layer and the ground layer and at least attenuates electric current that can flow between the signal layer and the ground layer. In the communication device, one of the first and second attenuation layers electrically connects the signal layer with a layer facing the signal layer across itself so as to stabilize electric potential of the signal layer.

In the above communication device, the second attenuation layer may be configured to have high resistivity so as to insulate the signal layer from the ground layer, and the first attenuation layer may be configured to have low resistivity that is lower than the high resistivity so as to pull up electric potential of the signal layer toward that of the power supply layer.

In at least one aspect, in the above communication device, the low resistivity is set at 10 to 1000 times the resistivity of the signal layer.

Alternatively, in the above communication device, the first attenuation layer may be configured to have high resistivity so as to insulate the signal layer from the power supply layer, and the second attenuation layer may be configured to have low resistivity that is lower than the high resistivity so as to pull down electric potential of the signal layer toward that of the ground layer.

In at least one aspect, in the above communication device, the low resistivity is set at 10 to 1000 times the resistivity of the signal layer.

In accordance with another aspect of the present invention, there is provided a communication device capable of transmitting a signal by two-dimensional diffusive signal transmission technology, comprising: a signal layer in which the signal is transmitted; a plurality of communication chips which are connected to the signal layer to transmit the signal by the two-dimensional diffusive signal transmission technology; a power supply layer which supplies electric power to each of the communication chips; a ground layer which is electrically connected to each of the communication chips as ground for the electric power; and a pull up unit which pulls up electric potential of the signal layer toward that of the power supply layer. In the communication device, the pull up unit includes: an attenuation layer which is placed between the signal layer and the power supply layer and attenuates electric current that can flow between the signal layer and the power supply layer; and a pull up resistor which connects the signal layer and the power supply layer.

In accordance with another aspect of the present invention, there is provided a communication device capable of transmitting a signal by two-dimensional diffusive signal transmission technology, comprising: a signal layer in which the signal is transmitted; a ground layer which is grounded; a plurality of communication chips which are connected to the signal layer and the ground layer to transmit the signal by the two-dimensional diffusive signal transmission technology; a power supply layer which supplies electric power to each of the communication chips; and a pull down unit which pulls down electric potential of the signal layer toward that of the ground layer. In the communication device, the pull down unit includes: an attenuation layer which is placed between the signal layer and the ground layer and attenuates electric current that can flow between the signal layer and the ground layer; and a pull down resistor which connects the signal layer and the ground layer.

In accordance with another aspect of the present invention, there is provided a communication device capable of transmitting a signal by two-dimensional diffusive signal transmission technology, comprising: first and second signal layers in which the signal is transmitted; a plurality of communication chips which are connected to the first and second signal layers to transmit the signal by the two-dimensional diffusive signal transmission technology; a power supply layer which supplies electric power to each of the communication chips; a ground layer which is electrically connected to each of the communication chips as ground for the electric power; a first attenuation layer which is placed between the first signal layer and the power supply layer, attenuates electric current that can flow between the first signal layer and the power supply layer, and pulls up electric potential of the first signal layer toward that of the power supply layer; and a second attenuation layer which is placed between the second signal layer and the ground layer, attenuates electric current that can flow between the second signal layer and the ground layer, and pulls down electric potential of the second signal layer toward that of the ground layer.

In at least one aspect, in the above communication device, resistivity of the first and second attenuation layers is set at 10 to 1000 times that of the first and second signal layers.

With the above communication devices in accordance with the present invention, the ill effects of the parasitic capacitance on each signal layer can be reduced while also stabilizing the electric potential of each signal layer at a prescribed level, by which high-quality signal transmission is realized.

### BRIEF DESCRIPTION OF THE ACCOMPANYING DRAWINGS

FIG. 1 is a top view showing a communication device in accordance with a first embodiment of the present invention.

FIG. 2 is a cross-sectional view of the communication device of the first embodiment taken along the line A-A′ shown in FIG. 1.

FIG. 3 is a circuit diagram for explaining the relationship among two adjacent DST chips, a power supply layer and a signal layer of the communication device of the first embodiment.

FIG. 4 is a cross-sectional view of a communication device in accordance with a second embodiment of the present invention.

FIG. 5 is a circuit diagram for explaining the relationship among two adjacent DST chips, a signal layer and a ground layer of the communication device of the second embodiment.

FIGS. 6A and 6B are a circuit diagram and a graph for explaining reduction of ill effects of parasitic capacitance on the signal layer of the communication device of the second embodiment.

FIG. 7 is a cross-sectional view of a communication device in accordance with a third embodiment of the present invention.

FIG. 8 is a circuit diagram for explaining the relationship among two adjacent DST chips, a power supply layer, a first signal layer, a second signal layer and a ground layer of the communication device of the third embodiment.

FIG. 9 is a cross-sectional view of a communication device in accordance with a fourth embodiment of the present invention.

FIG. 10 is a circuit diagram for explaining the relationship among two adjacent DST chips (200A), a power supply layer and a first signal layer and the relationship among two adjacent DST chips (200B), the power supply layer and a second signal layer in the communication device of the fourth embodiment.

FIG. 11 is a cross-sectional view of a communication device in accordance with a fifth embodiment of the present invention.

FIG. 12 is a circuit diagram for explaining the relationship among two adjacent DST chips (200A), a first signal layer and a ground layer 126 and the relationship among two adjacent DST chips (200B), a second signal layer and the ground layer in the communication device of the fifth embodiment.

### DETAILED DESCRIPTION OF THE EMBODIMENTS

Referring now to the drawings, a description will be given in detail of preferred embodiments in accordance with the present invention.

### First Embodiment

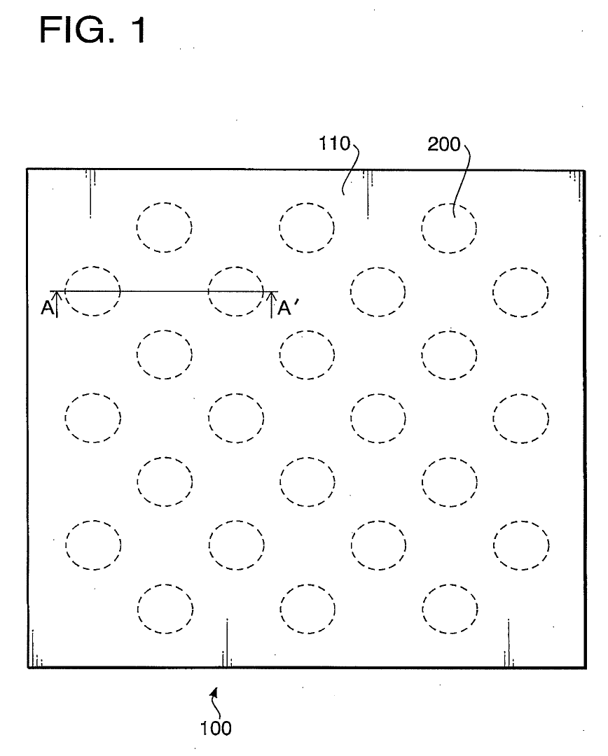

FIG. 1 is a top view showing a communication device 100 in accordance with a first embodiment of the present invention. The communication device 100 includes a signal transmission substrate 110 and a plurality of DST chips 200 installed in the signal transmission substrate 110. Incidentally, while a relatively small number of DST chips 200 are shown in the signal transmission substrate 110 in FIG. 1 for convenience of explanation, a larger number of DST chips 200 are installed in the signal transmission substrate 110 for practical use.

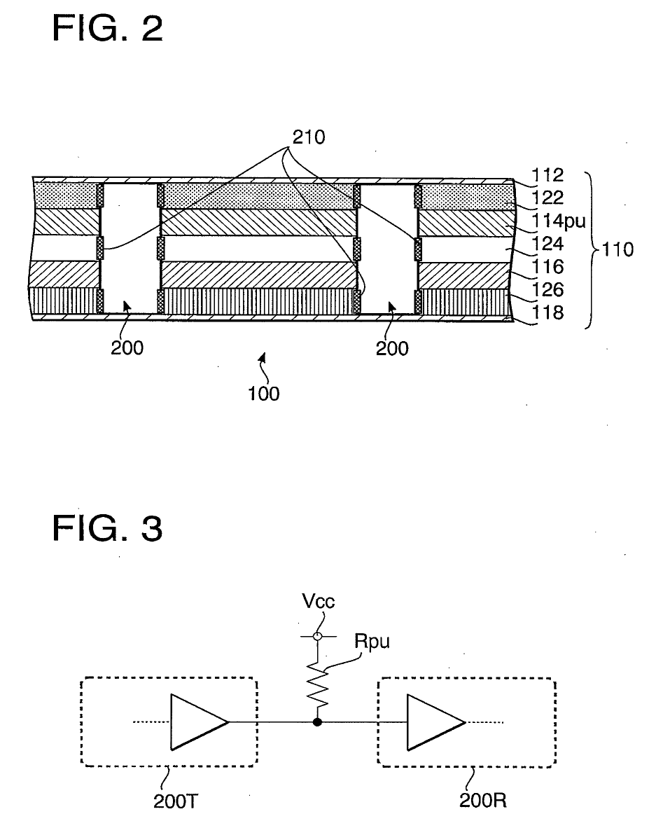

FIG. 2 is a cross-sectional view of the communication device 100 taken along the line A-A′ shown in FIG. 1. The signal transmission substrate 110 in the first embodiment has seven-layer structure, including a surface insulating layer 112, a power supply layer 122, a pull-up layer 114pu, a signal layer 124, an insulating layer 116, a ground layer 126 and a surface insulating layer 118 which are stacked in this order (listed from the top in FIG. 2). Each layer is stacked so as to make contact (surface-to-surface contact) with the adjacent layer(s) across its entire area.

The power supply layer 122, the signal layer 124 and the ground layer 126 are sheets having flexibility, stretchability and electrical conductivity (each formed of fabric into which conductive rubber or conductive material has been woven, for example). In each of the layers 122, 124 and 126, material having electrical conductivity has been evenly worked or woven into a sheet. The power supply layer 122 is a layer for supplying electric power to each of the DST chips 200. The signal layer 124 serves as a layer carrying the electric potential (voltage) of the 2D-DST signal being transmitted between two adjacent DST chips 200. The ground layer 126 serves as a layer holding the ground potential in the signal transmission substrate 110.

The surface insulating layers 112 and 118 and the insulating layer 116 are sheets having flexibility, stretchability and electrical insulating quality (each formed of insulating rubber, insulating film or fabric having insulating quality, for example). The surface insulating layer 112, as a layer exposed as the top surface (or under surface) of the signal transmission substrate 110, electrically insulates the power supply layer 122 from the outside. The surface insulating layer 118, as a layer exposed as the under surface (or top surface) of the signal transmission substrate 110, electrically insulates the ground layer 126 from the outside. The insulating layer 116 electrically insulates the signal layer 124 from the ground layer 126.

The pull-up layer 114pu is a conductive sheet having resistivity approximately 10-1000 times that of the signal layer 124, for example. The pull-up layer 114pu is formed of conductive material having flexibility and stretchability, such as low-resistivity silicon rubber, nonwoven fabric mixed with fiber having electrical conductivity, or knitted fabric woven from fiber having electrical conductivity. Even though the resistivity of the pull-up layer 114pu is lower than that of the insulating layer 116, etc., the pull-up layer 114pu is capable of effectively attenuating current flowing between the power supply layer 122 and the signal layer 124 to a level at which the current causes no trouble to the operation of the communication device 100.

Incidentally, the power supply layer 122 and the ground layer 126 are placed to (indirectly) sandwich the signal layer 124 in the first embodiment, since the power supply layer 122 and the ground layer 126 have relatively low impedance and are capable of functioning as shields. With this configuration, the insulation between the inside and the outside of the signal transmission substrate 110 is realized more remarkably.

Next, the DST chips 200 will be explained below.

Each DST chip 200 is embedded in the signal transmission substrate 110 to penetrate a part of the substrate 110 from the power supply layer 122 to the ground layer 126. Each DST chip 200 is electrically connected to the power supply layer 122, the signal layer 124 and the ground layer 126 via contact members 210 having electrical conductivity. Each DST chip 200 detects the changes in the voltage of the signal layer 124 and thereby transmits a signal to a destination according to the 2D-DST technology.

Next, the pull-up layer 114pu will be explained below.

The pull-up layer 114pu has less insulating quality compared to the insulating layer 116 and less electrical conductivity compared to the signal layer 124. Specifically, the resistivity of the pull-up layer 114pu is approximately 10-1000 times that of the signal layer 124 as mentioned above. Therefore, the pull-up layer 114pu, not perfectly insulating the signal layer 124 from the power supply layer 122, functions as a resistive layer which is neither an insulating layer nor a conductive layer.

FIG. 3 is a circuit diagram for explaining the relationship among two adjacent DST chips 200, the power supply layer 122 and the signal layer 124 of the communication device 100 of the first embodiment. In FIG. 3, the reference character “200T” represents a DST chip on the signal transmission side, “200R” represents a DST chip on the signal reception side, “Vcc” represents the electric potential of the power supply layer 122, and “Rpu” represents the resistance of the pull-up layer 114pu. The line connecting the two DST chips 200T and 200R represents the signal layer 124.

Since the power supply layer 122 and the signal layer 124 are placed to sandwich the pull-up layer 114pu as shown in FIG. 2, the pull-up layer 114pu in this configuration functions as a resistance placed between the power supply layer 122 and the signal layer 124. Thus, the signal layer 124 (between the transmission-side DST chip 200T and the reception-side DST chip 200R) is pulled up by the voltage (electric potential) Vcc of the power supply layer 122 via the resistance Rpu as shown in FIG. 3, for example. In other words, the pull-up layer 114pu functions as a pull-up resistance.

Thanks to the pull-up layer 114pu functioning as the pull-up resistance, the signal layer 124 stays in a state pulled up by the voltage (electric potential) of the power supply layer 122 while the power of the communication device 100 is OFF, by which the electric potential of the signal layer 124 (not disconnected (isolated) from the circuit of the communication device as shown in FIG. 3) is maintained in a stable state (i.e. Vcc). Consequently, malfunction, etc. of the communication device 100 (caused by unstable electric potential of the signal layer 124) is prevented from occurring.

In the following, several examples of various modifications of the above first embodiment will be described (as second through fifth embodiments) referring to figures, wherein reference characters identical or similar to those used in the first embodiment represent elements identical or equivalent to those in the first embodiment, and thus repeated explanation thereof will be omitted.

### Second Embodiment

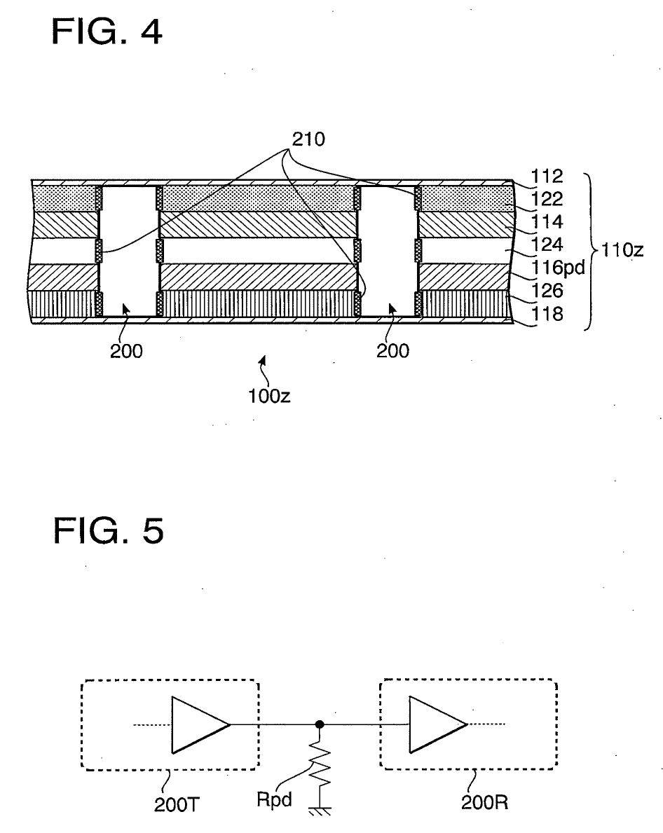

FIG. 4 is a cross-sectional view of a communication device 100z in accordance with a second embodiment of the present invention. FIG. 4 corresponds to the cross-sectional view of FIG. 2 used for the explanation of the first embodiment. The communication device 100z of FIG. 4 includes a signal transmission substrate 110z and a plurality of DST chips 200 installed in the signal transmission substrate 110z.

The signal transmission substrate 110z in the second embodiment has seven-layer structure, including a surface insulating layer 112, a power supply layer 122, an insulating layer 114, a signal layer 124, a pull-down layer 116pd, a ground layer 126 and a surface insulating layer 118 which are stacked in this order (listed from the top in FIG. 4). In short, the signal transmission substrate 110z has layered structure that is obtained by replacing the pull-up layer 114pu and the insulating layer 116 of the signal transmission substrate 110 in the first embodiment (see FIG. 2) with the insulating layer 114 and the pull-down layer 116pd, respectively.

The pull-down layer 116pd is a conductive sheet having resistivity approximately 10-1000 times that of the signal layer 124, for example. The pull-down layer 116pd is formed of conductive material having flexibility and stretchability, such as low-resistivity silicon rubber, nonwoven fabric mixed with fiber having electrical conductivity, or knitted fabric woven from fiber having electrical conductivity. Even though the resistivity of the pull-down layer 116pd is lower than that of the insulating layer 114, etc., the pull-down layer 116pd is capable of effectively attenuating current flowing between the signal layer 124 and the ground layer 126 to a level at which the current causes no trouble to the operation of the communication device 100z.

The pull-down layer 116pd has less insulating quality compared to the insulating layer 114 and less electrical conductivity compared to the signal layer 124. Specifically, the resistivity of the pull-down layer 116pd is approximately 10-1000 times that of the signal layer 124 as mentioned above. Therefore, the pull-down layer 116pd, not perfectly insulating the signal layer 124 from the ground layer 126, functions as a resistive layer which is neither an insulating layer nor a conductive layer.

FIG. 5 is a circuit diagram for explaining the relationship among two adjacent DST chips 200, the signal layer 124 and the ground layer 126 of the communication device 100z of the second embodiment. In FIG. 5, the reference character “Rpd” represents the resistance of the pull-down layer 116pd. The line connecting the two DST chips 200T and 200R represents the signal layer 124.

Since the signal layer 124 and the ground layer 126 are placed to sandwich the pull-down layer 116pd as shown in FIG. 4, the pull-down layer 116pd in this configuration functions as a resistance placed between the signal layer 124 and the ground layer 126. Thus, the signal layer 124 (between the transmission-side DST chip 200T and the reception-side DST chip 200R) is pulled down by the ground (ground potential) via the resistance Rpd as shown in FIG. 5, for example. In other words, the pull-down layer 116pd functions as a pull-down resistance.

Thanks to the pull-down layer 116pd functioning as the pull-down resistance, the signal layer 124 stays in a state pulled down by the electric potential of the ground layer 126 (ground potential) while the power of the communication device 100z is OFF, by which the electric potential of the signal layer 124 (not disconnected (isolated) from the circuit of the communication device as shown in FIG. 5) is maintained in a stable state (i.e. ground level). Consequently, malfunction, etc. of the communication device 100z (caused by unstable electric potential of the signal layer 124) is prevented from occurring.

Incidentally, whether the signal layer 124 should be pulled up or pulled down is determined depending on a communication protocol which is specified for the communication device.

By placing the pull-up layer 114pu or the pull-down layer 116pd in the signal transmission substrate (110, 110z) and letting the layer (114pu, 116pd) pull up or pull down (the electric potential of) the signal layer 124 as implemented in the communication devices (100, 100z) of the first and second embodiments, ill effects of parasitic capacitance on the signal layer 124 can be reduced compared to conventional communication devices. Specifically, in the first embodiment, the ill effects of the parasitic capacitance on the signal layer 124 are reduced by placing the pull-up layer 114pu (having less insulating quality (i.e. lower resistivity) compared to the insulating layer employed in conventional communication devices) between the power supply layer 122 and the signal layer 124. In the second embodiment, the ill effects are reduced by placing the pull-down layer 116pd (having less insulating quality (i.e. lower resistivity) compared to the insulating layer employed in conventional communication devices) between the signal layer 124 and the ground layer 126.

By reducing the ill effects of the parasitic capacitance by lowering the resistivity between conductive layers (between the power supply layer 122 and the signal layer 124, or between the signal layer 124 and the ground layer 126) of the signal transmission substrate (110, 110z) as described above, the throughput of the communication device can be increased.

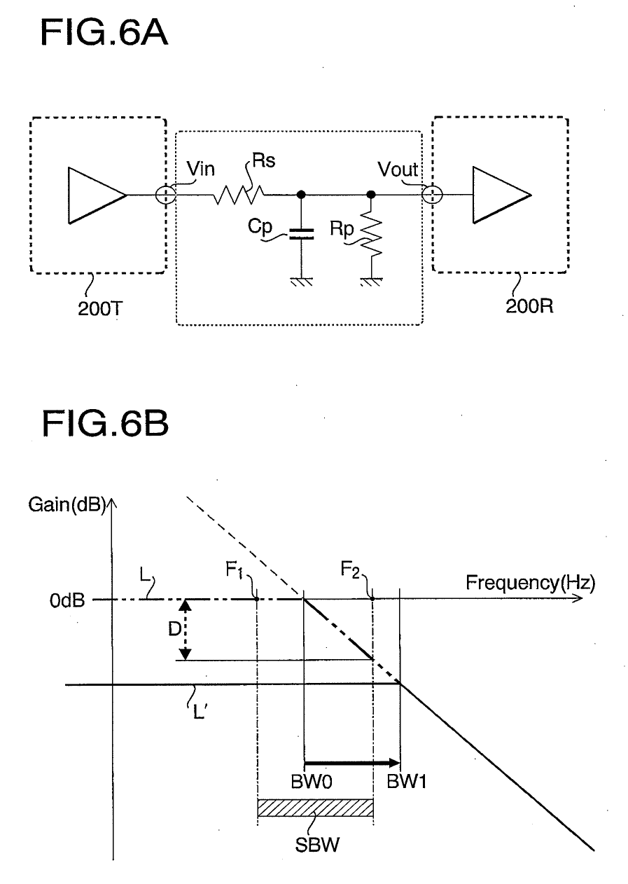

In the following, the reduction of the ill effects of the parasitic capacitance on the signal layer 124 of the communication device 100z of the second embodiment will be explained specifically by reference to FIGS. 4, 6A and 6B. FIG. 6A is a circuit diagram showing the relationship among two adjacent DST chips 200, the signal layer 124 and the ground layer 126 of the communication device 100z. FIG. 6B is a graph showing the relationship between the frequency and the gain of a signal transmitted in the circuit shown in FIG. 6A.

In FIG. 6A, the reference character “Vin” represents the input value (input voltage) of a signal inputted from the transmission-side DST chip 200T to the signal layer 124, “Vout” represents the output value (output voltage) of the signal outputted from the signal layer 124 to the reception-side DST chip 200R, “Rs” represents the resistance of the signal layer 124, “Rp” represents the resistance of the pull-down layer 116pd, and “Cp” represents composite parasitic capacitance of the parasitic capacitance occurring in the power supply layer 122, the signal layer 124 and the insulating layer 114 and the parasitic capacitance occurring in the pull-down layer 116pd.

In FIG. 6B, the line L represents a signal characteristic in a case where Rp>>Rs (that is, when the pull-down layer 116pd in the second embodiment is replaced with an insulating layer as in conventional communication devices), and the line L′ represents a signal characteristic in a case where Rp>Rs (second embodiment).

In the signal characteristic indicated by the line L, the gain of the transmission signal remains at 0 dB until the frequency reaches a frequency BW0. In other words, the input value Vin of the signal inputted from the transmission-side DST chip 200T to the signal layer 124 substantially equals the output value Vout of the signal outputted from the signal layer 124 to the reception-side DST chip 200R when the frequency of the transmission signal is below or equal to the frequency BW0. Meanwhile, in a high-frequency range above the frequency BW0, the gain of the transmission signal gradually drops as the frequency increases.

Assuming that a signal band width SBW shown in FIG. 6B (with a lower limit frequency F1 and an upper limit frequency F2) is necessary for the transmission of the signal in the signal layer 124, a signal amplitude difference “D” shown in FIG. 6B occurs between a first case where the frequency of the transmission signal is F1 and a second case where the frequency of the transmission signal is F2. In other words, in this case where the signal layer 124 is sandwiched between insulating layers, the gain of the transmission signal in the signal band width SBW can fluctuate within the amplitude difference D due to the significant ill effects of the parasitic capacitance on the signal layer 124. Consequently, the reception-side DST chip 200R might erroneously detect the changes in the voltage of the signal layer 124.

On the other hand, in the signal characteristic indicated by the line L′, the gain of the transmission signal remains constant and resists dropping until the frequency reaches a frequency BW1 (BW1>BW0), even though the constant gain is lower than 0 dB. At the point when the frequency of the transmission signal exceeds the frequency BW1, the gain starts dropping gradually.

Here, since the frequency BW1 is higher than the upper limit frequency F2 of the signal band width SBW, the gain of the transmission signal stays constant throughout the signal band width SBW. In other words, in the case where the pull-down layer 116pd (i.e. low-resistivity layer) is employed as a layer on one side of the signal layer 124, a wider frequency range free from the ill effects of the parasitic capacitance can be secured as compared with conventional communication devices. Consequently, the gain fluctuation of the transmission signal in the signal band width SBW is eliminated in the second embodiment. Thanks to the elimination of the gain fluctuation, the reception-side DST chip 200R is prevented from erroneously detecting the voltage changes of the signal layer 124, that is, the ill effects of the parasitic capacitance on the signal layer 124 are reduced and excellent signal transmission is realized in the case where the pull-down layer 116pd is employed as a layer on one side of the signal layer 124.

Next, how the wide frequency range (or the wide signal band width SBW) with a constant gain can be secured by lowering the resistance between the signal layer 124 and the ground layer 126 will be explained concretely by reference to the following expressions.

According to the circuit diagram of FIG. 6A, the following expression (1) holds:

$$\vert \frac{Vout}{Vin} \vert = \frac{Rp}{Rs + Rp} \frac{1}{\sqrt{1 + {( ω CpR )}^{2}}} \\ where R = \frac{RsRp}{Rs + Rp} \qquad ( 1 )$$

Here, Rp/(Rs+Pp) can be regarded as 1 when Rp>>Rs, and thus the following expression (2) is derived:

$$\vert \frac{Vout}{Vin} \vert \approx \frac{1}{\sqrt{1 + {( ω CpR )}^{2}}} \qquad ( 2 )$$

Therefore, the following expressions (3) and (4) are obtained:

$$\begin{matrix}BW 0 ( - 3 dB ) = \frac{1}{2 π CpRs} & ( 3 ) \\ BW 1 ( - 3 dB ) = \frac{1}{2 π CpR} & ( 4 )\end{matrix}$$

From the expressions (3) and (4), BW1>BW0 holds since R<Rs. Therefore, the frequency as the upper limit of the frequency range with a constant gain is increased from BW0 to BW1 (that is, the frequency range with a constant gain is widened) in the second embodiment by lowering the resistance between the signal layer 124 and the ground layer 126. Thanks to the widened frequency range with a constant gain, the gain fluctuation of the transmission signal is eliminated (that is, the ill effects of the parasitic capacitance on the signal layer 124 are eliminated in the signal band width SBW) in the second embodiment.

### Third Embodiment

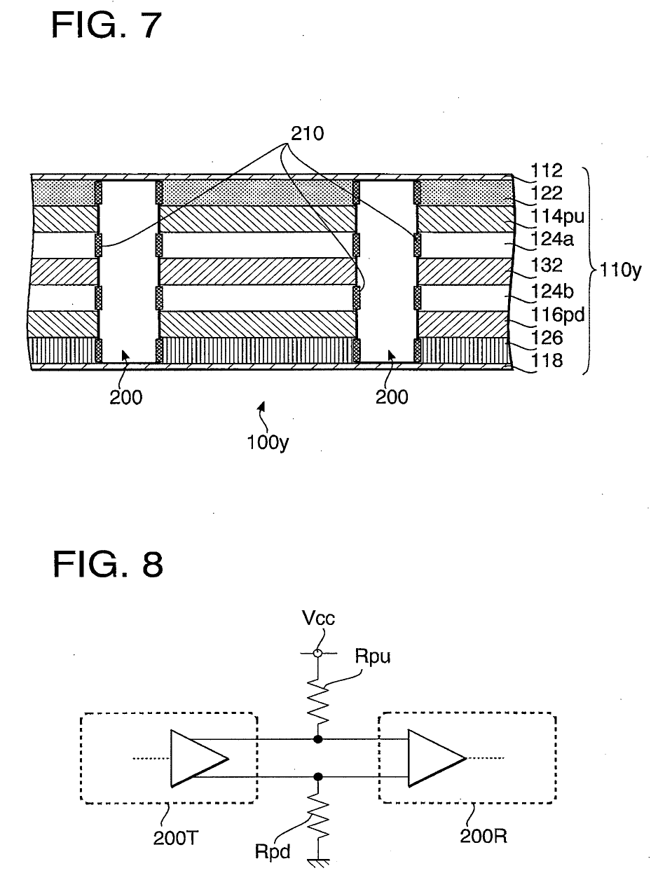

FIG. 7 is a cross-sectional view of a communication device 100y in accordance with a third embodiment of the present invention. FIG. 7 corresponds to the cross-sectional view of FIG. 2 used for the explanation of the first embodiment. The communication device 100y of FIG. 7 includes a signal transmission substrate 110y and a plurality of DST chips 200 installed in the signal transmission substrate 110y.

The signal transmission substrate 110y in the third embodiment has nine-layer structure, including a surface insulating layer 112, a power supply layer 122, a pull-up layer 114pu, a first signal layer 124a, an insulating layer 132, a second signal layer 124b, a pull-down layer 116pd, a ground layer 126 and a surface insulating layer 118 which are stacked in this order (listed from the top in FIG. 7).

In the communication device 100y, each DST chip 200 is electrically connected to the power supply layer 122, the first signal layer 124a, the second signal layer 124b and the ground layer 126 via contact members 210 having electrical conductivity. Each DST chip 200, being connected to the two signal layers 124a and 124b, is capable of transmitting two separate signals according to a prescribed algorithm. In the third embodiment, each DST chip 200 executes signal transmission according to a differential transmission method, for example, by use of the two signal layers 124a and 124b, by which signal transmission in a high frequency range, noise reduction, reduction of ill effects of the parasitic capacitance on both the first and second signal layers 124a and 124b, and the like are realized.

FIG. 8 is a circuit diagram for explaining the relationship among two adjacent DST chips 200, the power supply layer 122, the first signal layer 124a, the second signal layer 124b and the ground layer 126 of the communication device 100y of the third embodiment.

As shown in FIG. 7, the power supply layer 122 and the first signal layer 124a are placed to sandwich the pull-up layer 114pu. Meanwhile, the second signal layer 124b and the ground layer 126 are placed to sandwich the pull-down layer 116pd. Therefore, the first signal layer 124a (between the transmission-side DST chip 200T and the reception-side DST chip 200R) is pulled up by the voltage (electric potential) Vcc of the power supply layer 122 via the resistance Rpu, and the second signal layer 124b (between the transmission-side DST chip 200T and the reception-side DST chip 200R) is pulled down by the ground (ground potential) via the resistance Rpd, as shown in FIG. 8, for example.

By configuring the communication device 100y of the third embodiment to implement the pull up by the pull-up layer 114pu and the pull down by the pull-down layer 116pd as above, excellent stability of the electric potential of each signal layer, reduction of the ill effects of the parasitic capacitance on each signal layer, and the like are realized similarly to the first and second embodiments.

Incidentally, parasitic capacitance may also occur between the first signal layer 124a and the second signal layer 124b. Therefore, further reduction of the ill effects of the parasitic capacitance on each signal layer is possible by, for example, forming the insulating layer 132 (between the first and second signal layers 124a and 124b) with material having resistivity close to that of the pull-up layer 114pu and the pull-down layer 116pd.

### Fourth Embodiment

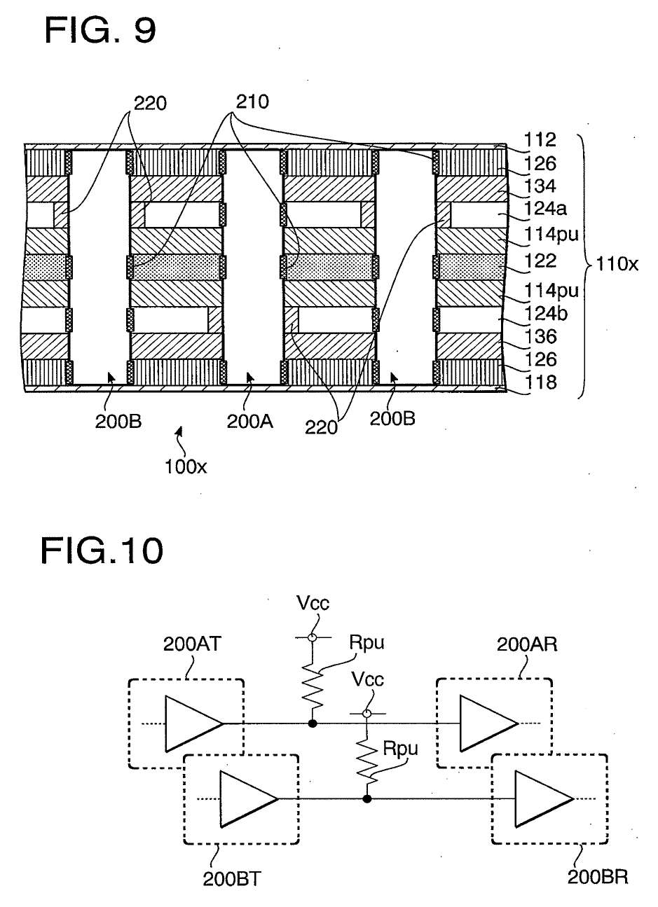

FIG. 9 is a cross-sectional view of a communication device 100x in accordance with a fourth embodiment of the present invention. FIG. 9 corresponds to the cross-sectional view of FIG. 2 used for the explanation of the first embodiment. The communication device 100x of FIG. 9 includes a signal transmission substrate 110x and a plurality of DST chips 200 installed in the signal transmission substrate 110x.

The signal transmission substrate 110x in the fourth embodiment has eleven-layer structure, including a surface insulating layer 112, a ground layer 126, an insulating layer 134, a first signal layer 124a, a pull-up layer 114pu, a power supply layer 122, a pull-up layer 114pu, a second signal layer 124b, an insulating layer 136, a ground layer 126 and a surface insulating layer 118 which are stacked in this order (listed from the top in FIG. 9).

In the communication device 100x, the DST chips are classified into two groups: DST chips 200A and DST chips 200B. Each DST chip 200A is electrically connected to the power supply layer 122, the first signal layer 124a and the ground layers 126 via contact members 210 having electrical conductivity, while being insulated from the second signal layer 124b by an insulating member 220 having electrical insulating quality. Thus, each DST chip 200A executes the signal transmission by detecting the changes in the voltage of the first signal layer 124a. Meanwhile, each DST chip 200B is electrically connected to the power supply layer 122, the second signal layer 124b and the ground layers 126 via contact members 210 having electrical conductivity, while being insulated from the first signal layer 124a by an insulating member 220 having electrical insulating quality. Thus, each DST chip 200B executes the signal transmission by detecting changes in the voltage of the second signal layer 124b. Incidentally, the DST chips 200A and 200B have substantially the same configuration even though they are supposed to process different signals.

FIG. 10 is a circuit diagram for explaining the relationship among two adjacent DST chips 200A, the power supply layer 122 and the first signal layer 124a, and the relationship among two adjacent DST chips 200B, the power supply layer 122 and the second signal layer 124b in the communication device 100x of the fourth embodiment. In FIG. 10, the reference character “200AT” represents a DST chip 200A on the signal transmission side, “200AR” represents a DST chip 200A on the signal reception side, “200BT” represents a DST chip 200B on the signal transmission side, and “200BR” represents a DST chip 200B on the signal reception side.

As shown in FIG. 9, the power supply layer 122 and the first signal layer 124a are placed to sandwich the (upper) pull-up layer 114pu. Meanwhile, the power supply layer 122 and the second signal layer 124b are placed to sandwich the (lower) pull-up layer 114pu. Therefore, the first signal layer 124a (between the transmission-side DST chip 200AT and the reception-side DST chip 200AR) is pulled up by the voltage Vcc of the power supply layer 122 via the resistance Rpu, and the second signal layer 124b (between the transmission-side DST chip 200BT and the reception-side DST chip 200BR) is also pulled up by the voltage Vcc of the power supply layer 122 via the resistance Rpu, as shown in FIG. 10, for example.

By configuring the communication device 100x of the fourth embodiment to implement the pull up of the signal layers 124a and 124b by the pull-up layers 114pu as above, excellent stability of the electric potential of each signal layer, reduction of the ill effects of the parasitic capacitance on each signal layer, etc. are realized similarly to the first through third embodiments.

### Fifth Embodiment

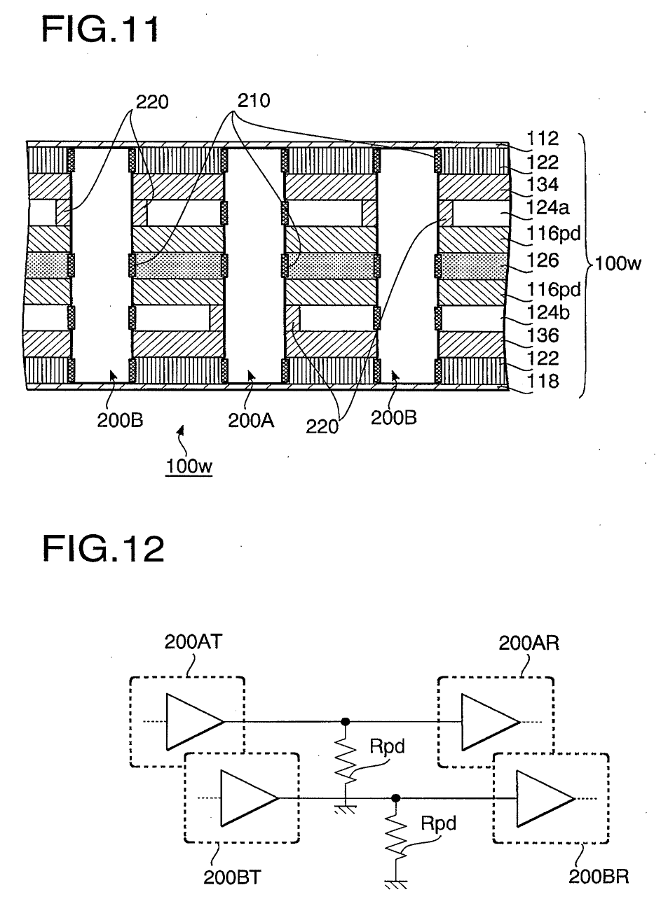

FIG. 11 is a cross-sectional view of a communication device 100w in accordance with a fifth embodiment of the present invention. FIG. 11 corresponds to the cross-sectional view of FIG. 2 used for the explanation of the first embodiment. The communication device 100w of FIG. 11 includes a signal transmission substrate 110w and a plurality of DST chips 200 installed in the signal transmission substrate 110w.

The signal transmission substrate 110w in the fifth embodiment has eleven-layer structure, including a surface insulating layer 112, a power supply layer 122, an insulating layer 134, a first signal layer 124a, a pull-down layer 116pd, a ground layer 126, a pull-down layer 116pd, a second signal layer 124b, an insulating layer 136, a power supply layer 122 and a surface insulating layer 118 which are stacked in this order (listed from the top in FIG. 11).

FIG. 12 is a circuit diagram for explaining the relationship among two adjacent DST chips 200A, the first signal layer 124a and the ground layer 126, and the relationship among two adjacent DST chips 200B, the second signal layer 124b and the ground layer 126 in the communication device 100w of the fifth embodiment.

As shown in FIG. 11, the first signal layer 124a and the ground layer 126 are placed to sandwich the (upper) pull-down layer 116pd. Meanwhile, the second signal layer 124b and the ground layer 126 are placed to sandwich the (lower) pull-down layer 116pd. Therefore, the first signal layer 124a (between the transmission-side DST chip 200AT and the reception-side DST chip 200AR) is pulled down by the ground (ground potential) via the resistance Rpd, and the second signal layer 124b (between the transmission-side DST chip 200BT and the reception-side DST chip 200BR) is also pulled down by the ground (ground potential) via the resistance Rpd, as shown in FIG. 12, for example.

By configuring the communication device 100w of the fifth embodiment to implement the pull down of the signal layers 124a and 124b by the pull-down layers 116pd as above, excellent stability of the electric potential of each signal layer, reduction of the ill effects of the parasitic capacitance on each signal layer, and the like are realized similarly to the first through fourth embodiments.

While a description has been given above of preferred embodiments in accordance with the present invention, the present invention is not to be restricted by the particular illustrative embodiments and a variety of modifications, design changes, and the like are possible without departing from the scope and spirit of the present invention described in the appended claims.

For example, the total resistance of the pull-up layer 114pu or pull-down layer 116pd (for the circuit driving the signal layer 124) does not necessarily have to be set at the resistance necessary for the pull up or pull down of the signal layer 124. In this case, the pull up or pull down of the signal layer 124 can be implemented by adjusting the resistance by placing a pull-up resistor or pull-down resistor as an extra component. Since the resistance can be adjusted by the pull-up resistor or pull-down resistor, precise management of the condition of contact between the power supply layer 122 and the pull-up layer 114pu or between the ground layer 126 and the pull-down layer 116pd becomes unnecessary, by which the manufacturing yield of the communication device can be increased.

This application claims priority of Japanese Patent Application No. P2006-137666, filed on May 17, 2006. The entire subject matter of the application is incorporated herein by reference.

What is claimed is:

1. A communication device capable of transmitting a signal by two-dimensional diffusive signal transmission technology, comprising:
a signal layer in which the signal is transmitted;
a plurality of communication chips which are connected to the signal layer to transmit the signal by the two-dimensional diffusive signal transmission technology;
a power supply layer which supplies electric power to each of the communication chips;
a ground layer which is electrically connected to each of the communication chips as ground for the electric power; and
an attenuation layer which is placed between the signal layer and the power supply layer, attenuates electric current that can flow between the signal layer and the power supply layer, and pulls up electric potential of the signal layer toward that of the power supply layer.

2. The communication device according to claim 1, wherein resistivity of the attenuation layer is set at 10 to 1000 times that of the signal layer.

3. The communication device according to claim 1, wherein:
the layered structure of the communication device includes a first ground layer, a first signal layer, a first attenuation layer, a power supply layer, a second attenuation layer, a second signal layer and a second ground layer in this order, and
the communication chips include: first communication chips which are connected to the first signal layer, the power supply layer and the first and second ground layers to transmit a first signal by the two-dimensional diffusive signal transmission technology; and second communication chips which are connected to the second signal layer, the power supply layer and the first and second ground layers to transmit a second signal by the two-dimensional diffusive signal transmission technology, and
the first attenuation layer is placed between the first signal layer and the power supply layer, attenuates electric current that can flow between the first signal layer and the power supply layer, and pulls up electric potential of the first signal layer toward that of the power supply layer, and
the second attenuation layer is placed between the second signal layer and the power supply layer, attenuates electric current that can flow between the second signal layer and the power supply layer, and pulls up electric potential of the second signal layer toward that of the power supply layer.

4. A communication device capable of transmitting a signal by two-dimensional diffusive signal transmission technology, comprising:
a signal layer in which the signal is transmitted;
a ground layer which is grounded;
a plurality of communication chips which are connected to the signal layer and the ground layer to transmit the signal by the two-dimensional diffusive signal transmission technology;
a power supply layer which supplies electric power to each of the communication chips; and
an attenuation layer which is placed between the signal layer and the ground layer, attenuates electric current that can flow between the signal layer and the ground layer, and pulls down electric potential of the signal layer toward that of the ground layer.

5. The communication device according to claim 4, wherein resistivity of the attenuation layer is set at 10 to 1000 times that of the signal layer.

6. The communication device according to claim 4, wherein:
the layered structure of the communication device includes a first power supply layer, a first signal layer, a first attenuation layer, a ground layer, a second attenuation layer, a second signal layer and a second power supply layer in this order, and
the communication chips include: first communication chips which are connected to the first signal layer, the first and second power supply layers and the ground layer to transmit a first signal by the two-dimensional diffusive signal transmission technology; and second communication chips which are connected to the second signal layer, the first and second power supply layers and the ground layer to transmit a second signal by the two-dimensional diffusive signal transmission technology, and
the first attenuation layer is placed between the first signal layer and the ground layer, attenuates electric current that can flow between the first signal layer and the ground layer, and pulls down electric potential of the first signal layer toward that of the ground layer, and
the second attenuation layer is placed between the second signal layer and the ground layer, attenuates electric current that can flow between the second signal layer and the ground layer, and pulls down electric potential of the second signal layer toward that of the ground layer.

7. A communication device capable of transmitting a signal by two-dimensional diffusive signal transmission technology, comprising:
a signal layer in which the signal is transmitted;
a plurality of communication chips which are connected to the signal layer to transmit the signal by the two-dimensional diffusive signal transmission technology;
a power supply layer which supplies electric power to each of the communication chips;
a ground layer which is electrically connected to each of the communication chips as ground for the electric power; and
a first attenuation layer which is placed between the signal layer and the power supply layer and at least attenuates electric current that can flow between the signal layer and the power supply layer; and
a second attenuation layer which is placed between the signal layer and the ground layer and at least attenuates electric current that can flow between the signal layer and the ground layer, wherein:
one of the first and second attenuation layers electrically connects the signal layer with a layer facing the signal layer across itself so as to stabilize electric potential of the signal layer.

8. The communication device according to claim 7, wherein:
the second attenuation layer has high resistivity so as to insulate the signal layer from the ground layer, and
the first attenuation layer has low resistivity that is lower than the high resistivity so as to pull up electric potential of the signal layer toward that of the power supply layer.

9. The communication device according to claim 8, wherein the low resistivity is set at 10 to 1000 times the resistivity of the signal layer.

10. The communication device according to claim 7, wherein:
the first attenuation layer has high resistivity so as to insulate the signal layer from the power supply layer, and
the second attenuation layer has low resistivity that is lower than the high resistivity so as to pull down electric potential of the signal layer toward that of the ground layer.

11. The communication device according to claim 10, wherein the low resistivity is set at 10 to 1000 times the resistivity of the signal layer.

12. A communication device capable of transmitting a signal by two-dimensional diffusive signal transmission technology, comprising:
a signal layer in which the signal is transmitted;
a plurality of communication chips which are connected to the signal layer to transmit the signal by the two-dimensional diffusive signal transmission technology;
a power supply layer which supplies electric power to each of the communication chips;
a ground layer which is electrically connected to each of the communication chips as ground for the electric power; and
a pull up unit which pulls up electric potential of the signal layer toward that of the power supply layer, wherein:
the pull up unit includes:
an attenuation layer which is placed between the signal layer and the power supply layer and attenuates electric current that can flow between the signal layer and the power supply layer; and
a pull up resistor which connects the signal layer and the power supply layer.

13. A communication device capable of transmitting a signal by two-dimensional diffusive signal transmission technology, comprising:
a signal layer in which the signal is transmitted;
a ground layer which is grounded;
a plurality of communication chips which are connected to the signal layer and the ground layer to transmit the signal by the two-dimensional diffusive signal transmission technology;
a power supply layer which supplies electric power to each of the communication chips; and
a pull down unit which pulls down electric potential of the signal layer toward that of the ground layer, wherein:
the pull down unit includes:
an attenuation layer which is placed between the signal layer and the ground layer and attenuates electric current that can flow between the signal layer and the ground layer; and
a pull down resistor which connects the signal layer and the ground layer.

14. A communication device capable of transmitting a signal by two-dimensional diffusive signal transmission technology, comprising:
first and second signal layers in which the signal is transmitted;
a plurality of communication chips which are connected to the first and second signal layers to transmit the signal by the two-dimensional diffusive signal transmission technology;
a power supply layer which supplies electric power to each of the communication chips;
a ground layer which is electrically connected to each of the communication chips as ground for the electric power;
a first attenuation layer which is placed between the first signal layer and the power supply layer, attenuates electric current that can flow between the first signal layer and the power supply layer, and pulls up electric potential of the first signal layer toward that of the power supply layer; and
a second attenuation layer which is placed between the second signal layer and the ground layer, attenuates electric current that can flow between the second signal layer and the ground layer, and pulls down electric potential of the second signal layer toward that of the ground layer.

15. The communication device according to claim 14, wherein resistivity of the first and second attenuation layers is set at 10 to 1000 times that of the first and second signal layers.
